(19) United States
(12) Patent Application Publication
(10) Pub. No.: US 2023/0395366 A1
(43) Pub. Date: Dec. 7, 2023

(54) DEFECT REMOVAL DEVICE, DEFECT REMOVAL METHOD, PATTERN FORMING METHOD, AND METHOD OF MANUFACTURING ELECTRONIC DEVICE

(71) Applicant: FUJIFILM Corporation, Tokyo (JP)

(72) Inventors: Akihiko OHTSU, Shizuoka (JP); Masahiro YOSHIDOME, Shizuoka (JP); Yukihisa KAWADA, Shizuoka (JP); Ryo SAITO, Shizuoka (JP)

(73) Assignee: FUJIFILM Corporation, Tokyo (JP)

(21) Appl. No.: 18/451,810

(22) Filed: Aug. 17, 2023

Related U.S. Application Data
(63) Continuation of application No. PCT/JP2022/004604, filed on Feb. 7, 2022.

(30) Foreign Application Priority Data
Feb. 25, 2021 (JP) 2021-028759

(51) Int. Cl. H01L 21/02; H01L 21/66; G01N 21/95; G01N 21/88

(52) U.S. Cl. CPC H01L 21/02098; H01L 22/24; H01L 22/12; G01N 21/9501; G01N 2021/8838; G01N 21/8851; G01N 2021/8835; G01N 2021/8861; G01N 21/8806

(57) ABSTRACT

Provided are a defect removal device and a defect removal method capable of removing defects of a semiconductor substrate with high accuracy, and a pattern forming method and a method of manufacturing an electronic device using the semiconductor substrate from which defects on a surface are removed. The defect removal device includes: a first light source unit that emits incidence light for detecting a defect on a semiconductor substrate; a surface defect measurement unit including a detection unit that detects the defect on the semiconductor substrate based on radiated light radiated by reflection or scattering of the incidence light from the defect of the semiconductor substrate; a removal unit that irradiates the semiconductor substrate with laser light to remove the defect based on position information of the defect on the semiconductor substrate; and an alignment unit that adjusts optical axes of the incidence light and the laser light, in which the optical axes of the incidence light and the laser light are adjusted by the alignment unit such that the incidence light and the laser light are emitted to the semiconductor substrate.

### CROSS-REFERENCE TO RELATED APPLICATIONS

This application is a Continuation of PCT International Application No. PCT/JP2022/004604 filed on Feb. 7, 2022, which claims priority under 35 U.S.C. § 119(a) to Japanese Patent Application No. 2021-028759 filed on Feb. 25, 2021. The above applications are hereby expressly incorporated by reference, in their entirety, into the present application.

### BACKGROUND OF THE INVENTION

### 1. Field of the Invention

The present invention relates to a defect removal device and a defect removal method capable of removing defects on a surface of a semiconductor substrate using laser ablation, a pattern forming method using a semiconductor substrate from which defects on a surface are removed, and a method of manufacturing an electronic device.

### 2. Description of the Related Art

Currently, various semiconductor devices are manufactured using a semiconductor substrate such as a silicon substrate. In a case where defects such as foreign matter are present on a surface of a semiconductor substrate, the formation of a gate in a transistor is insufficient during the manufacturing of a semiconductor device, and the semiconductor device to be manufactured may be a defective product, for example, due to disconnection of a wiring line. In a case where defects such as foreign matter are present on a surface of a semiconductor substrate as described above, the defects affect the yield of the semiconductor device.

The defects such as foreign matter of the semiconductor substrate are removed, for example, by wet cleaning such as RCA cleaning. In the wet cleaning, the semiconductor substrate is uniformly cleaned, but there is a case where the foreign matter cannot be completely removed. In this case, dry cleaning of removing defects such as foreign matter by laser irradiation may be performed.

For example, the dry cleaning uses a laser processing method described in JP2017-60991A in which a work piece is processed with laser light having a relatively low photon energy and a relatively low fluence.

In the laser cleaning method described in JP2017-60991A, a semiconductor wafer is used as an object and the entire surface of the object is irradiated with a first pulse to induce excitation of an electron system on the surface of the object without searching for foreign matter of nanoparticles and metal contaminants. Due to the excitation of the electron system, a coherent excitation layer is formed. Before extinction of the excitation layer formed by the excitation of the electron system, the surface of the object is irradiated with a second pulse to remove foreign matter positioned on the surface of the object.

### SUMMARY OF THE INVENTION

In JP2017-60991A, the entire surface of the object is irradiated with the first pulse and the second pulse without searching for foreign matter. Therefore, foreign matter may or may not be present at each of irradiation positions. Therefore, the removal accuracy of foreign matter is poor.

In addition, in JP2017-60991A, in order to remove foreign matter, the first pulse and the second pulse are irradiated, and irradiation regions need to match with each other. Therefore, the removal of foreign matter is not easy, and it is difficult to maintain the removal accuracy of foreign matter.

An object of the present invention is to provide a defect removal device and a defect removal method capable of removing defects of a semiconductor substrate with high accuracy, and a pattern forming method and a method of manufacturing an electronic device using the semiconductor substrate from which defects on a surface are removed.

According to one aspect of the present invention for achieving the above-described object, there is provided a defect removal device using position information of a defect on a semiconductor substrate, the defect removal device comprising a removal unit that irradiates the semiconductor substrate with laser light to remove the defect based on the position information of the defect on the semiconductor substrate.

It is preferable that the defect removal device further comprises a surface defect measurement unit that measures whether or not the defect is present on the semiconductor substrate to obtain the position information of the defect on the semiconductor substrate.

According to another aspect of the present invention, there is provided a defect removal device comprising: a surface defect measuring device that measures whether or not a defect is present on a semiconductor substrate to obtain position information of the defect on the semiconductor substrate; and a removal device that irradiates the semiconductor substrate with laser light to remove the defect based on the position information of the defect on the semiconductor substrate obtained by the surface defect measuring device.

According to still another aspect of the present invention, there is provided a defect removal device comprising: a surface defect measurement unit including a first light source unit and a detection unit, in which the first light source unit emits incidence light for detecting a defect on a semiconductor substrate and the detection unit detects the defect on the semiconductor substrate based on radiated light radiated by reflection or scattering of the incidence light from the defect of the semiconductor substrate; a removal unit that irradiates the semiconductor substrate with laser light to remove the defect; and an alignment unit that adjusts optical axes of the incidence light and the laser light, in which the optical axes of the incidence light and the laser light are adjusted by the alignment unit such that the incidence light and the laser light are emitted to the semiconductor substrate.

It is preferable that the removal unit emits the laser light to the defect detected by the surface defect measurement unit.

It is preferable that the optical axes of the incidence light and the laser light are adjusted to be the same by the alignment unit such that the incidence light and the laser light are emitted to the semiconductor substrate.

It is preferable that the surface defect measurement unit includes a light receiving unit that receives the radiated light and a condenser lens that collects the radiated light to the light receiving unit, and it is preferable that, in a case where the laser light is emitted to the defect, a shutter is disposed between the condenser lens and the surface of the semiconductor substrate.

It is preferable that the alignment unit includes an optical element that allows incidence of the incidence light and the laser light, emits the incident incidence light and the incident laser light in the same direction, and separates the incident incidence light and the incident laser light such that first separated light separated from the incidence light and second separated light separated from the laser light are emitted in the same direction, a first mirror that causes the incidence light to be incident into the optical element, a second mirror that causes the laser light to be incident into the optical element, and a photodetector that detects at least an intensity of light for the first separated light of the incidence light and the second separated light of the laser light that are separated by the optical element, and it is preferable that inclinations of the first mirror and the second mirror are adjustable.

It is preferable that the surface defect measurement unit obtains position information of the defect on the semiconductor substrate.

It is preferable that the surface defect measurement unit includes a first light source unit that emits incidence light for detecting the defect on the semiconductor substrate and a light receiving unit that receives radiated light radiated by reflection or scattering of the incidence light from the defect on the semiconductor substrate.

It is preferable that the surface defect measurement unit includes a storage unit that stores the position information.

It is preferable that the defect removal device further comprises a supply unit that supplies carrier gas to a surface of the semiconductor substrate.

It is preferable that the incidence light is laser light that continuously oscillates.

It is preferable that the laser light is laser light that pulse-oscillates.

According to still another aspect of the present invention, there is provided a defect removal method using position information of a defect on a semiconductor substrate, the defect removal method comprising irradiating the semiconductor substrate with laser light to remove the defect based on the position information of the defect on the semiconductor substrate.

According to still another aspect of the present invention, there is provided a defect removal method using position information of a defect on a semiconductor substrate, the defect removal method comprising: a step of measuring whether or not the defect is present on the semiconductor substrate to obtain the position information of the defect on the semiconductor substrate; and a removal step of irradiating the semiconductor substrate with laser light to remove the defect based on the position information of the defect on the semiconductor substrate.

According to an aspect of the present invention, there is provided a defect removal method comprising: a detection step of emitting incidence light for detecting a defect on a semiconductor substrate to detect the defect on the semiconductor substrate; and a removal step of emitting laser light of which an optical axis is adjusted to be the same as that of the incidence light to the semiconductor substrate to remove the defect.

It is preferable that, in the removal step, the laser light is emitted to the defect detected in the detection step along the same optical axis as that of the incidence light.

It is preferable that the defect removal method further comprises an adjustment step of adjusting the optical axes of the incidence light and the laser light before the detection step or before the removal step.

It is preferable that, in the removal step, the defect is removed in a state where carrier gas is supplied to a surface of the semiconductor substrate.

It is preferable that, in the detection step, the defect on the semiconductor substrate is detected using a light receiving unit that receives radiated light radiated by reflection or scattering of the incidence light from the defect on the semiconductor substrate and a condenser lens that collects the radiated light to the light receiving unit, and it is preferable that, in the removal step, a shutter is disposed between the condenser lens and a surface of the semiconductor substrate such that the laser light is emitted to the detected defect.

It is preferable that, in the detection step, position information of the defect on the semiconductor substrate is obtained.

It is preferable that the incidence light is laser light that continuously oscillates. It is preferable that the laser light is laser light that pulse-oscillates.

According to still another aspect of the present invention, there is provided a pattern forming method comprising: a step of forming a resist film on a surface of a semiconductor substrate using the semiconductor substrate from which a defect on the surface is removed using the defect removal method according to the aspect of the present invention; and a step of forming a pattern on the resist film.

According to still another aspect of the present invention, there is provided a method of manufacturing an electronic device comprising: a step of forming a resist film on a surface of a semiconductor substrate using the semiconductor substrate from which a defect on the surface is removed using the defect removal method according to the aspect of the present invention; and a step of forming a pattern of an electronic device on the resist film.

According to the aspect of the present invention, a defect on a semiconductor substrate can be removed with high accuracy.

In addition, a pattern can be formed and an electronic device can be manufactured using the semiconductor substrate from which a defect is removed.

### BRIEF DESCRIPTION OF THE DRAWINGS

FIG. 1 is a schematic diagram showing a first example of a defect removal device according to an embodiment of the present invention.

FIG. 2 is a schematic diagram showing an example of a defect detected by the defect removal device according to the embodiment of the present invention.

FIG. 3 is a schematic cross-sectional view showing another example of a supply unit of carrier gas in the defect removal device according to the embodiment of the present invention.

FIG. 4 is a schematic diagram showing a second example of the defect removal device according to the embodiment of the present invention.

FIG. 5 is a schematic diagram showing a third example of the defect removal device according to the embodiment of the present invention.

### DESCRIPTION OF THE PREFERRED EMBODIMENTS

Hereinafter, a defect removal device, a defect removal method, a pattern forming method, and a method of manufacturing an electronic device according to the present invention will be described in detail based on a preferred embodiment shown in the accompanying drawings.

The drawings described below are exemplary drawings for describing the present invention, and the present invention is not limited to the drawings described below.

In the following description, a numerical range indicated by the expression “to” includes numerical values described on both sides. For example, in a case where ε satisfies a numerical value εₐ to a numerical value ε_{b}, the range of ε is a range including a numerical value Σₐ and a numerical value ε_{b}, and is expressed by εₐ≤ε≤ε_{b} in terms of mathematical symbols.

Unless specified otherwise, the meaning of an angle such as “an angle represented by a specific numerical value”, “perpendicular”, or “orthogonal” includes a case where an error range is generally allowable in the technical field.

### First Example of Defect Removal Device

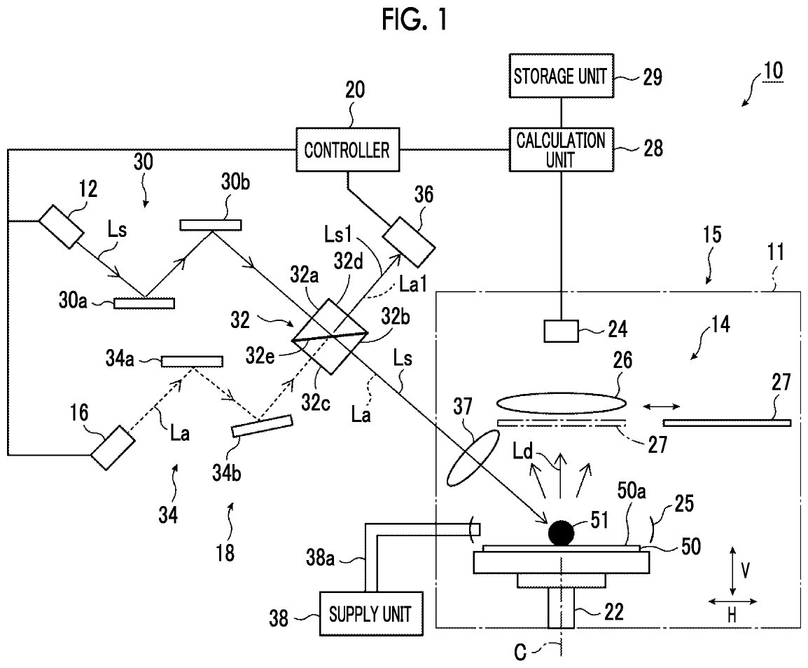

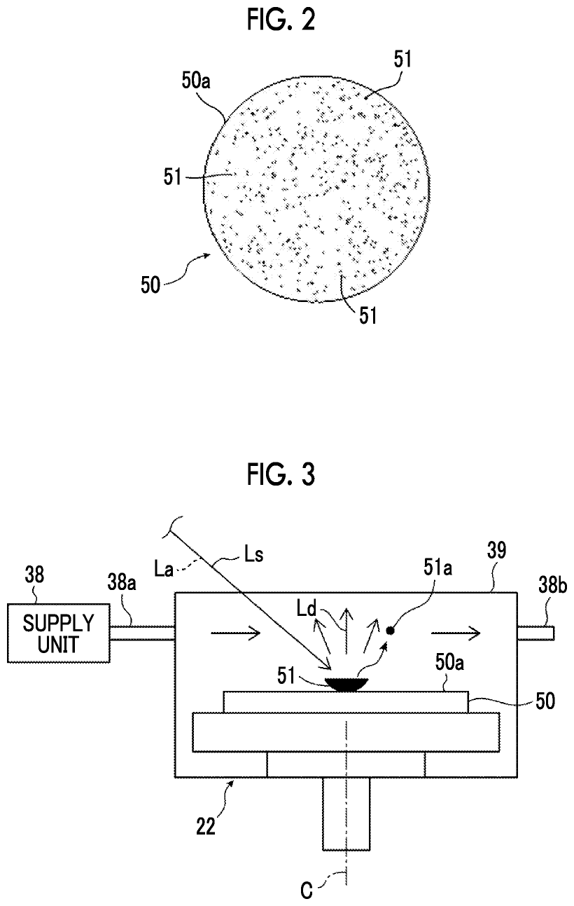

FIG. 1 is a schematic diagram showing a first example of the defect removal device according to the embodiment of the present invention, and FIG. 2 is a schematic diagram showing an example of a defect detected by the defect removal device according to the embodiment of the present invention.

A defect removal device 10 shown in FIG. 1 includes a surface defect measurement unit 15, a second light source 16, an alignment unit 18, and a controller 20. Various components of the defect removal device 10 are controlled by the controller 20.

The defect removal device 10 detects defects 51 on a surface 50a of a semiconductor substrate 50, and removes the defects 51 on the surface 50a of the semiconductor substrate 50 using laser ablation. The semiconductor substrate 50 is, for example, a disk-shaped substrate.

Incidence light Ls for defect detection and laser light La for defect removal are emitted along the same optical axis.

Here, the same optical axis is a state where an optical axis of the incidence light Ls and an optical axis of the laser light La match with each other. In a case where a difference between the optical axis of the incidence light Ls and the optical axis of the laser light La is 0.1 degrees or less, the optical axes are assumed to be the same.

Specifically, the match of the optical axes represents that positions where the incidence light Ls and the laser light La are incident into a transmitting reflecting surface 32e of an optical element 32 described below match with each other.

In addition, aligning the optical axes represents making the optical axis of the incidence light Ls and the optical axis of the laser light La match with each other. In a case where a difference between the optical axis of the incidence light Ls and the optical axis of the laser light La is 0.1 degrees or less, the optical axes match with each other.

The defect removal device 10 includes a stage 22 placed on the semiconductor substrate 50. The stage 22 is rotatable around a rotation axis C, can change a position of the semiconductor substrate 50 in a height direction V, and can change a position of the semiconductor substrate 50 in a direction H orthogonal to the height direction V.

For example, the stage 22, a light receiving unit 24 described below, a condenser lens 26 described below, a shutter 27 described below, and a condenser lens 37 described below are disposed in, for example, a chamber 11, and the detection of the defects 51 and the removal of the defects 51 in the semiconductor substrate 50 are performed in the chamber 11.

The surface defect measurement unit 15 performs the detection of the defects 51 on the surface 50a of the semiconductor substrate 50 and measurement of whether or not the defects 51 are present on the surface 50a of the semiconductor substrate 50. The surface defect measurement unit 15 includes a first light source unit 12 and a detection unit 14. The first light source unit 12 emits the incidence light Ls for detecting the defects 51 on the surface 50a of the semiconductor substrate 50. It is preferable that the incidence light Ls irradiated from the first light source unit 12 is laser light that continuously oscillates. The laser light that continuously oscillates is also called continuous wave (CW) laser light.

A wavelength of the incidence light Ls is not particularly limited. The incidence light Ls is, for example, ultraviolet light and may be visible light or other light. Here, the ultraviolet light refers to light in a wavelength range of less than 400 nm, and the visible light refers to light in a wavelength range of 400 to 800 nm.

Regarding an incidence angle of the incidence light Ls, it is assumed that all directions parallel to the surface 50a of the semiconductor substrate 50 are 0° and a direction perpendicular to the surface 50a of the semiconductor substrate 50 is 90°. At this time, in a case where the incidence angle of the incidence light Ls is defined as a range from minimum 0° to maximum 90°, the incidence angle of the incidence light Ls is 0° or more and 900 or less and preferably more than 0° and less than 90°.

The detection unit 14 detects the defects 51 on the surface 50a of the semiconductor substrate 50 based on radiated light Ld radiated by reflection or scattering of the incidence light Ls from the defects 51 on surface 50a of the semiconductor substrate 50. In addition, the detection unit 14 may obtain position information of the defects 51 on the surface 50a of the semiconductor substrate 50. The detection unit 14 will be described below in detail.

The second light source 16 emits the laser light La to the defects 51 detected by the detection unit 14 and removes the defects 51 by ablation with the laser light La emitted from the second light source 16.

It is preferable that the laser light La irradiated from the second light source 16 is laser light that pulse-oscillates. The laser light that pulse-oscillates is also called pulsed laser light.

The second light source 16 is used as a femtosecond laser, a nanosecond laser, a picosecond laser, an attosecond laser, or the like. As the femtosecond laser, for example, a Ti:Sapphire laser can be used.

In addition, it is preferable that the femtosecond laser has a pulse duration of 1000 femtoseconds or less. It is preferable that the nanosecond laser has a pulse duration of 1000 nanoseconds or less.

The alignment unit 18 adjusts the optical axes of the incidence light Ls and the laser light La and, for example, aligns the optical axes of the incidence light Ls and the laser light La. The optical axes of the incidence light Ls and the laser light La are adjusted to be the same by the alignment unit 18 such that the incidence light Ls and the laser light La are emitted to the surface 50a of the semiconductor substrate 50. The alignment unit 18 will be described below in detail.

(Detection Unit)

The detection unit 14 includes the light receiving unit 24 that receives the radiated light Ld radiated by reflection or scattering of the incidence light Ls from the surface 50a of the semiconductor substrate 50. The light receiving unit 24 is disposed, for example, above the surface 50a of the semiconductor substrate 50. In a case where the radiated light Ld is received, the light receiving unit 24 outputs, for example, a light-receiving signal to a calculation unit 28.

The condenser lens 26 is provided between the surface 50a of the semiconductor substrate 50 and the light receiving unit 24. The radiated light Ld generated from the incidence light Ls is collected to the light receiving unit 24 by the condenser lens 26. The radiated light Ld can be efficiently collected to the light receiving unit 24 by the condenser lens 26.

The light receiving unit 24 receives the radiated light Ld on a high angle side. The light receiving on the high angle side refers to the light receiving in a range of more than 800 and 900 or less at the above-described incidence angle.

In the detection unit 14 shown in FIG. 1, one light receiving unit 24 is provided. However, the number of the light receiving units is not particularly limited and may be plural. In a case where the number of the light receiving units is plural, for example, a light receiving unit 25 may be disposed around the semiconductor substrate 50. The light receiving unit 25 receives the radiated light Ld on a low angle side. The light receiving on the low angle side refers to the light receiving in a range of 0° or more and 800 or less at the above-described incidence angle.

In a case where the radiated light Ld is received, the light receiving unit 24 and the light receiving unit 25 output a light-receiving signal to the calculation unit 28. In addition, the light receiving unit 24 and the light receiving unit 25 are configured with, for example, an optical sensor such as a photomultiplier. The light receiving unit 24 and the light receiving unit 25 can receive unpolarized light or polarized light.

In addition, the detection unit 14 includes the shutter 27 that is disposed between the condenser lens 26 and the surface 50a of the semiconductor substrate 50. The shutter 27 prevents contamination of the condenser lens 26 caused by laser ablation described below. The shutter 27 prevents an evaporant 51a (refer to FIG. 3) that is formed by evaporation of the defects 51 formed by laser ablation from being attached to the condenser lens 26. As a result, a decrease in the sensitivity of the radiated light Ld in the light receiving unit 24 can be suppressed, and a decrease in defect detection accuracy can be suppressed.

In a case where the laser light La is emitted to the defects 51, the shutter 27 is disposed in front of the condenser lens 26. By disposing the shutter 27 in front of the condenser lens 26, the shutter 27 may be closed.

In a case where the detection unit 14 is operated to detect the defects 51, the shutter 27 is retreated from the front of the condenser lens 26 and is disposed in the other cases. Retreating the shutter 27 from the front of the condenser lens 26 will also referred to as opening the shutter 27.

The disposition position of the shutter 27 changes depending on a moving mechanism (not shown). The shutter 27 is formed of, for example, a metal plate or a plastic plate.

The surface defect measurement unit 15 includes the calculation unit 28 and a storage unit 29.

The calculation unit 28 obtains the light-receiving signal output in a case where the radiated light Ld is received by the light receiving unit 24, and detects the defects 51.

That is, in a case where the radiated light Ld is received, the light receiving unit 24 outputs a light-receiving signal to a calculation unit 28. In the calculation unit 28, in a case where the radiated light Ld based on which it is determined that the defects 51 are present on the surface 50a of the semiconductor substrate 50 is detected is not generated, for example, the light receiving unit 24 does not output the light-receiving signal to the calculation unit 28. In this case, it is determined that the defects 51 are not present on the surface 50a of the semiconductor substrate 50. This way, in the calculation unit 28, whether or not the defects 51 are present on the surface 50a of the semiconductor substrate 50 is detected based on information regarding whether or not the radiated light Ld is received by the light receiving unit 24.

In addition, the calculation unit 28 can also calculate the position information of the detected defects and the sizes of the defects based on the information regarding the radiated light received by the light receiving unit 24. The position information of the defects refers to information regarding position coordinates of the defects on the surface 50a of the semiconductor substrate 50. Regarding the position coordinates, for example, a reference position common to a plurality of semiconductor substrates 50 is set in advance, and the position coordinates are set as an origin point of the reference position.

The light receiving unit 24 receives the radiated light Ld radiated by reflection or scattering of the incidence light Ls irradiated from the first light source unit 12 from the defects 51 on the surface 50a of the semiconductor substrate 50. In the light receiving unit 24, the radiated light Ld is detected as bright spots. The calculation unit 28 calculates the sizes of the defects that cause the bright spots, that is, the detection sizes based on the sizes of standard particles among the sizes of the bright spots including the information of the radiated light from the defects received by the light receiving unit 24. The calculation of the detection sizes based on the sizes of the standard particles is performed using a calculation device in a commercially available surface inspection device or using a well-known calculation method. The calculation unit 28 acquires position information regarding an irradiation position of the incidence light Ls from the controller 20, and the light receiving unit 24 obtains the position information of the defects 51 on the surface 50a of the semiconductor substrate 50 and the information regarding the sizes of the defects 51 based on the information regarding the radiated light from the defects 51. The obtained position information of the defects 51 on the surface 50a of the semiconductor substrate 50 and the obtained information regarding the sizes of the defects 51 are stored in the storage unit 29. This way, the surface defect measurement unit 15 obtains the position information of the defects 51 on the surface 50a of the semiconductor substrate 50 and the information regarding the sizes of the defects 51.

The storage unit 29 is not particularly limited as long as it can store the position information of the defects 51 such as foreign matter on the surface 50a of the semiconductor substrate 50 and the information regarding the sizes thereof. For example, various storage media such as a volatility memory, a non-volatile memory, a hard disk, or a solid state drive (SSD) can be used.

The controller 20 acquires the position information of the incidence light Ls irradiated from the first light source unit 12 on the surface 50a of the semiconductor substrate 50. The stage 22 is controlled by the controller 20. In order to irradiate a region that is not irradiated with the incidence light Ls on the surface 50a of the semiconductor substrate 50 with the incidence light Ls, the controller 20 drives the stage 22 and changes the irradiation position of the surface 50a of the semiconductor substrate 50.

In the surface defect measurement unit 15, the entire region of the surface 50a of the semiconductor substrate 50 is irradiated with the incidence light Ls, and the defect 51 is detected at each of the irradiation positions based on the information regarding whether or not the radiated light Ld is received by the light receiving unit 24.

Further, in the surface defect measurement unit 15, the entire region of the surface 50a of the semiconductor substrate 50 is irradiated with the incidence light Ls, and the position information of the defect on the surface 50a of the semiconductor substrate 50 and the information regarding the size of the defect at each of the irradiation positions can also be obtained based on the information regarding the radiated light Ld received by the light receiving unit 24. As a result, the position information of the defects on the entire surface 50a of the semiconductor substrate 50 and the information regarding the sizes of the defects can be obtained. That is, the two-dimensional position information of the defects on the surface 50a of the semiconductor substrate 50 and the information regarding the sizes of the defects can be obtained.

As the surface defect measurement unit 15, for example, a surface inspection device (Surfscan SP5; manufactured by KLA Corporation) can be used.

The surface defects of the semiconductor substrate 50 are measured by the surface defect measurement unit 15. As a result, the position information of the defects such as foreign matter on the surface 50a of the semiconductor substrate 50 and the sizes of the defects are detected. For example, the defects 51 on the surface 50a of the semiconductor substrate 50 can be represented as shown in FIG. 2. The representation of the defects 51 on the surface 50a of the semiconductor substrate 50 is called mapping. The position information of the defects 51 on the surface 50a of the semiconductor substrate 50 and the information regarding the sizes are stored in the storage unit 29. The position information of the defects 51 on the surface 50a of the semiconductor substrate 50 and the information regarding the sizes are called mapping information.

(Alignment Unit)

The alignment unit 18 includes, for example, the optical element 32, a first mirror 30 that causes the incidence light Ls to be incident into the optical element 32, a second mirror 34 that causes the laser light La to be incident into the optical element 32, and a photodetector 36.

The optical element 32 allows incidence of the incidence light Ls and the laser light La, emits the incident incidence light Ls and the incident laser light La in the same direction, and separates the incident incidence light Ls and the incident laser light La such that first separated light Ls1 separated from the incidence light Ls and second separated light La1 separated from the laser light La are emitted in the same direction.

Here, the emission in the same direction represents that the incidence light Ls and the laser light La are emitted from a common surface. Specifically, the surface from which the incidence light Ls and the laser light La are emitted is an emission surface 32b. In addition, the first separated light Ls1 and the second separated light La1 are emitted from a common surface. Specifically, the surface from which the first separated light Ls1 and the second separated light La1 are emitted is a surface 32d.

The photodetector 36 detects at least an intensity of light for the first separated light Ls1 of the incidence light Ls and the second separated light La1 of the laser light La that are separated by the optical element 32.

The photodetector 36 is disposed to face the surface 32d of the optical element 32 from which the first separated light Ls1 and the second separated light La1 are emitted. The photodetector 36 is connected to the controller 20.

In addition, the condenser lens 37 that collects the incidence light Ls and the laser light La to the defects 51 on the surface 50a of the semiconductor substrate 50 is provided between the emission surface 32b of the optical element 32 and the surface 50a of the semiconductor substrate 50.

A mirror 30a into which the incidence light Ls emitted from the first light source unit 12 is incident and a mirror 30b where the incidence light Ls reflected from the mirror 30a is incident and reflected to be incident into the optical element 32 are provided. The mirror 30a and the mirror 30b configure the first mirror 30. Inclinations of the mirror 30a and the mirror 30b in the first mirror 30 are adjustable, and a mirror adjustment unit that adjusts the inclinations of the mirror 30a and the mirror 30b may be provided.

The number of mirrors in the first mirror 30 is not limited to 2 and may be 1 or may be 3 or more. The optical axis of the incidence light Ls is adjusted by the mirror 30a and the mirror 30b. Therefore, the number of mirrors where the accuracy of the optical axis and the easy adjustment of the optical axis can be simultaneously achieved is preferable.

A mirror 34a into which the laser light La emitted from the second light source 16 is incident and a mirror 34b where the laser light La reflected from the mirror 34a is incident and reflected to be incident into the optical element 32 are provided. The mirror 34a and the mirror 34b configure the second mirror 34. Inclinations of the mirror 34a and the mirror 34b in the second mirror 34 are adjustable, and a mirror adjustment unit that adjusts the inclinations of the mirror 34a and the mirror 34b may be provided.

The number of mirrors in the second mirror 34 is not limited to 2 and may be 1 or may be 3 or more. The optical axis of the incidence light Ls is adjusted by the mirror 34a and the mirror 34b. Therefore, the number of mirrors where the accuracy of the optical axis and the easy adjustment of the optical axis can be simultaneously achieved is preferable.

In addition, the mirror adjustment unit adjusts the inclinations of the mirrors, for example, using a piezoelectric element.

The optical element 32 is configured by, for example, a beam splitter. The form of the beam splitter is not limited to a cube type and may be a flat plate type. In addition, as the optical element 32, in addition to the beam splitter, a partially reflecting mirror can also be used.

The incidence light Ls is incident into a first incident surface 32a of the optical element 32, transmits through the transmitting reflecting surface 32e, and is emitted from the emission surface 32b facing the first incident surface 32a.

In addition, the incidence light Ls incident into the first incident surface 32a of the optical element 32 is reflected and separated into the first separated light Ls1 by the transmitting reflecting surface 32e, is emitted from the surface 32d to the photodetector 36, and is incident into the photodetector 36. The first separated light Ls1 that is separated by the transmitting reflecting surface 32e and emitted from the surface 32d is a part of the incidence light Ls.

The laser light La is incident into a second incident surface 32c of the optical element 32, is reflected from the transmitting reflecting surface 32e, and is emitted from the emission surface 32b facing the first incident surface 32a.

In addition, the laser light La incident into the second incident surface 32c of the optical element 32 is separated into the second separated light La1 by transmitting through the transmitting reflecting surface 32e, is emitted from the surface 32d facing the second incident surface 32c to the photodetector 36, and is incident into the photodetector 36. The second separated light La1 that is separated and is emitted from the surface 32d is a part of the laser light La.

This way, the incidence light Ls and the laser light La are emitted in the same direction from the emission surface 32b by the optical element 32. The first separated light Ls1 and the second separated light La1 are emitted in the same direction from the surface 32d.

The degree of separation, for example, the amounts of light of the first separated light Ls1 and the second separated light La1 can be adjusted by adjusting a reflectivity or a transmittance of the transmitting reflecting surface 32e of the optical element 32.

In addition, the degree of separation can also be adjusted by disposing a polarizing plate or the like before the separation to adjust the polarization direction.

The photodetector 36 detects at least an intensity of light for the first separated light Ls1 that is a part of the incidence light Ls and the second separated light La1 that is a part of the laser light La. It is preferable that the photodetector 36 can measure a diameter of the incident light and an intensity distribution of the incident light. For example, a beam profiler is used. The photodetector 36 can measure the diameter of the first separated light Ls1, the diameter of the second separated light La1, and the intensity distributions of the first separated light Ls1 and the second separated light La1.

In the beam profiler, for example, a beam profiler where optical sensors are two-dimensionally disposed is used. As the beam profiler where optical sensors are two-dimensionally disposed, for example, a charge coupled device (CCD) camera is used.

In a case where the optical axes of the incidence light Ls and the laser light La are aligned, for example, in a state where the incidence light Ls and the laser light La are emitted, the photodetector 36 measures the intensities of the first separated light Ls1 and the second separated light La1 emitted from the surface 32d of the optical element 32.

In a case where the optical axes of the incidence light Ls and the laser light La match with each other, the positions where the incidence light Ls and the laser light La are emitted to the transmitting reflecting surface 32e are the same, and the optical axes of the first separated light Ls1 and the second separated light La1 emitted from the surface 32d of the optical element 32 match with each other. Therefore, the intensity of light is increased. Accordingly, for example, a state where the intensity of light measured by the photodetector 36 is the highest is a state where the optical axes of the incidence light Ls and the laser light La are aligned. In this case, the mirror 30a and 30b of the first mirror 30 and the mirrors 34a and 34b of the second mirror 34 are adjusted such that the intensity of light measured by the photodetector 36 is the highest.

The match of the optical axes of the incidence light Ls and the laser light La is obtained, for example, based on the intensity of light of the photodetector 36, and whether or not the optical axes match with each other is detected by the controller 20.

In addition, the detection of whether or not the optical axes match with each other is not limited to using the intensity of light. For example, the intensity distribution of light can also be used. In this case, the intensity distribution of light where the optical axes match with each other is measured in advance. By comparing the intensity distribution of measured light to the intensity distribution of light where the optical axes match with each other, whether or not the optical axes match with each other can be detected.

In the defect removal device 10, as described above, the optical axes of the incidence light Ls and the laser light La are made to match with each other, the detection unit 14 measures the defects 51 on the surface 50a of the semiconductor substrate 50 using the incidence light Ls, and the laser light La is irradiated along the same optical axis as that of the incidence light Ls. As a result, the defects 51 of the semiconductor substrate 50 can be removed with higher accuracy.

During the alignment of the defects, there may be a case where the sufficient accuracy cannot be obtained due to error of the alignment caused by a difference in device, backlash error caused by the stage operation, or the like. However, by making the optical axes of the incidence light Ls used for the defect inspection and the laser light La used for the defect removal match with each other, the defect inspection and the defect removal of the semiconductor substrate 50 can be performed using one device, movement between devices is unnecessary, and the stage 22 does not need to be moved. Therefore, the defects can be removed accurately and simply. Further, an increase in the size of the device configuration can be suppressed.

In addition, for example, the defect removal device 10 includes a supply unit 38 that supplies carrier gas to the surface 50a of the semiconductor substrate 50. The supply unit 38 supplies carrier gas to the surface 50a of the semiconductor substrate 50, for example, using a pipe 38a. In addition, in the chamber 11, for example, an outlet unit (not shown) configured by a pipe and a valve is provided. By opening the valve, the carrier gas can flow out from the chamber 11 to the outside.

The supply unit 38 includes: a gas supply source (not shown) such as a tank that contains carrier gas; a regulator (pressure adjuster; not shown) that is connected to the gas supply source; and an adjusting valve (not shown) that controls the supply amount of the carrier gas. For example, the regulator and the adjusting valve are connected through a tube. As the carrier gas, for example, helium gas or argon gas is used.

The evaporant 51a (refer to FIG. 3) formed by ablating the defects 51 is removed by the carrier gas from the surface 50a of the semiconductor substrate 50, and the evaporant 51a is prevented from being attached to the condenser lens 26. In addition, reattachment of the evaporant 51a (refer to FIG. 3) to the surface 50a of the semiconductor substrate 50 is also suppressed by the carrier gas. The evaporant 51a (refer to FIG. 3) will also be referred to as an ablation product.

The defect removal device 10 has the configuration in which the shutter 27 and the supply unit 38 are provided. However, the present invention is not limited to this configuration. The defect removal device 10 may have a configuration in which the shutter 27 and the supply unit 38 are not provided, may have a configuration in which only the shutter 27 among the shutter 27 and the supply unit 38 is provided, or may have a configuration in which only the supply unit 38 is provided.

FIG. 3 is a schematic cross-sectional view showing another example of the supply unit of carrier gas in the defect removal device according to the embodiment of the present invention.

The defect removal device 10 includes the supply unit 38 that supplies carrier gas to the surface 50a of the semiconductor substrate 50. However, the present invention is not limited to this configuration.

For example, as shown in FIG. 3, a container unit 39 that stores the semiconductor substrate 50 placed on the stage 22 may be provided. The supply unit 38 is connected to the container unit 39 through the pipe 38a.

An outlet unit 38b that causes the carrier gas to flow out from the container unit 39 to the outside is provided in the container unit 39. The outlet unit 38b is configured by, for example, a pipe and a valve. By opening the valve, the carrier gas can flow out from the container unit 39 to the outside.

In a state where the semiconductor substrate 50 is stored in the container unit 39, the carrier gas is supplied from the supply unit 38. By providing the container unit 39, contamination of the condenser lens 26 can be suppressed. Therefore, the shutter 27 (refer to FIG. 1) is unnecessary.

In the container unit 39, a window portion (not shown) through which the incidence light Ls and the laser light La can transmit is provided such that the incidence light Ls and the laser light La enter the container unit 39, and a window portion (not shown) through which the radiated light Ld can transmit is provided such that the radiated light Ld exits the container unit 39.

In the container unit 39, a heater (not shown) for performing a flushing process may be provided. By heating the container unit 39 using the heater in a state where the carrier gas is supplied to the container unit 39, for example, foreign matter such as an ablation attachment or adsorption gas in the container unit 39 is removed. As a result, the cleanliness in the container unit 39 can be increased, and contamination of the semiconductor substrate 50 can be suppressed. As the heater, for example, an infrared lamp or a xenon flash lamp is used.

In the carrier gas supplied from the supply unit 38, as long as the moisture content is 0.00001 vol ppm or more and 0.1 vol ppm or less, in a case where defects are detected in the chamber 11 or in the container unit 39, contamination of the surface 50a of the semiconductor substrate 50 can be reduced. For example, in a case where moisture content in the carrier gas is high, impurity is eluted to a small amount of moisture attached to a pipe surface of the carrier gas, an inner surface of the chamber 11 or an inner surface of the container unit 39, and the impurity is reattached to the surface 50a of the semiconductor substrate 50 such that the number of defects may increase. In a case where the moisture content in the carrier gas is in the above-described range, these problems are suppressed.

In addition, in a case where the moisture content is low and the carrier gas passes through the vicinity of the semiconductor substrate 50, the surface 50a of the semiconductor substrate 50 is likely to be charged. As a result, charged particles that float in the chamber 11 or in the container unit 39 are likely to be generated in the surface 50a of the semiconductor substrate 50, or particles that float in the vicinity during transport in a transport system are likely to be guided to the surface 50a of the semiconductor substrate 50. In addition, reattachment of a product formed as a result of laser ablation is likely to occur. However, in a case where the moisture content in the carrier gas is in the above-described range, the reattachment is suppressed.

The moisture content in the carrier gas can be measured using an atmospheric pressure ionization mass spectrometer (API-MS) (for example, manufactured by Nippon Api Co., Ltd.).

A method of adjusting the moisture content is not particularly limited, and the adjustment can be implemented by performing a gas purification step of removing moisture (water vapor) in the raw material gas. In particular, by adjusting the number of times of purification or a filter, the moisture content in the carrier gas can be adjusted.

The flow rate of the carrier gas is desirably 1.69×10⁻³ to 1.69 Pa·m³/sec (1 to 1000 seem (standard cubic centimeter per minute)).

In the defect removal device 10 shown in FIG. 1, the controller 20 causes the detection unit 14 to detect the defects 51 such as foreign matter on the surface 50a of the semiconductor substrate 50 using the incidence light Ls. In a case where the defects 51 are detected, the optical axis of the laser light La is aligned with the optical axis of the incidence light Ls. Therefore, by irradiating the laser light La without aligning the irradiation positions of the laser light La, the defects 51 on the surface 50a of the semiconductor substrate 50 are irradiated with the laser light La. As a result, the defects 51 on the surface 50a of the semiconductor substrate 50 are removed. This way, the optical axes of the incidence light Ls and the laser light La match with each other. Therefore, the defects 51 of the semiconductor substrate 50 can be removed with higher accuracy. By repeating the detection of the defects 51 using the incidence light Ls and the removal of the defects 51 using the laser light La, the defects 51 on the surface 50a of the semiconductor substrate 50 can be removed with higher accuracy. Further, the defects 51 can be efficiently removed without performing alignment or the like.

In addition, for example, in a state where a plurality of semiconductor substrates 50 are stored in a storage container (not shown) in the form of shelves, the semiconductor substrates 50 can also be transported from the outside to the defect removal device 10.

The storage container is, for example, a front opening unified pod (FOUP). By using the storage container, the semiconductor substrates 50 can be transported to the defect removal device 10 in a state where they are sealed without being exposed to outside air. As a result, contamination of the semiconductor substrate 50 can be suppressed.

As a device of transporting the semiconductor substrate 50 from the storage container to the stage 22, a device used for transport between processes of semiconductor wafers in a well-known semiconductor manufacturing device can be appropriately used.

### First Example of Defect Removal Method

The defect removal method includes: a detection step of emitting the incidence light Ls for detecting the defects 51 on the surface 50a of the semiconductor substrate 50 to detect the defects 51 on the surface 50a of the semiconductor substrate 50; and a removal step of emitting laser light La of which an optical axis is adjusted to be the same as that of the incidence light Ls to the surface 50a of the semiconductor substrate 50 to remove the defects 51. It is preferable that, in the removal step, the laser light La is emitted to the defects 51 detected in the detection step along the same optical axis as that of the incidence light Ls.

In addition, it is preferable that the defect removal method further includes an adjustment step of adjusting the optical axes of the incidence light Ls and the laser light La before the detection step or before the removal step.

In addition, it is preferable that, in the removal step, the defects 51 are removed in a state where the carrier gas is supplied.

The detection step includes a step of measuring whether or not the defects 51 are present on the surface 50a of the semiconductor substrate 50 to obtain the position information of the defects 51 on the surface 50a of the semiconductor substrate 50.

In the removal step, the detected defects 51 on the surface 50a of the semiconductor substrate 50 are irradiated with the laser light La to remove the defects 51. The defect removal method will be specifically described.

In the defect removal method, first, an adjustment step of aligning the optical axes of the incidence light Ls and the laser light La is performed before the detection step. In the adjustment step, in the defect removal device 10 of FIG. 1, the incidence light Ls is emitted from the first light source unit 12. In a case where the incidence light Ls is incident into the first incident surface 32a of the optical element 32, the first separated light Ls1 is emitted from the surface 32d and is incident into the photodetector 36.

The laser light La is emitted from the second light source 16. In a case where the laser light La is incident into the second incident surface 32c, the second separated light La1 is emitted from the surface 32d and incident into the photodetector 36. The photodetector 36 measures, for example, an intensity of light for the first separated light Ls1 and the second separated light La1.

As described above, in a case where the optical axes of the incidence light Ls and the laser light La match with each other, the optical axes of the first separated light Ls1 and the second separated light La1 also match with each other such that the intensity of light increases. Therefore, the inclinations or the like of the mirror 30a and 30b of the first mirror 30 and the mirrors 34a and 34b of the second mirror 34 are adjusted such that the intensity of light measured by the photodetector 36 is the highest. As a result, the optical axes of the incidence light Ls and the laser light La can be aligned. Since the optical axes only need to be adjusted in the removal step, the adjustment step may be performed before the detection step or before the removal step.

After aligning the optical axes of the incidence light Ls and the laser light La in the adjustment step, the incidence light Ls for detecting the defects 51 on the semiconductor substrate 50 is emitted from the first light source unit 12, and the detection step of detecting the defects 51 on the semiconductor substrate 50 is performed. In the detection step, the radiated light Ld radiated by reflection or scattering of the incidence light Ls from the defects 51 on the semiconductor substrate 50 is collected to the light receiving unit 24 by the condenser lens 26. In a case where the radiated light Ld is received, the light receiving unit 24 outputs a light-receiving signal to a calculation unit 28. As a result, the defects 51 are detected.

The calculation unit 28 can identify the positions of the defects 51 on the surface 50a of the semiconductor substrate 50 based on the radiated light Ld received by the light receiving unit 24, and can detect the position information of the defects such as foreign matter on the surface 50a of the semiconductor substrate 50 and the sizes. As a result, for example, the defects 51 on the surface 50a of the semiconductor substrate 50 can be represented as shown in FIG. 2.

In the detection step, in a case where the defects 51 are detected as described above, the emission of the incidence light Ls from the first light source unit 12 is stopped. Next, for example, the shutter 27 is disposed in front of the condenser lens 26.

Next, the laser light La from the second light source 16 is emitted to the detected defects 51 along the same optical axis as that of the incidence light Ls to evaporate and remove the defects 51 (removal step). That is, the defects 51 are removed by laser ablation using the laser light La.

In the removal step, in a state where the optical axes of the incidence light Ls and the laser light La are aligned, the detection of the defects 51 and the removal of the defects 51 are performed through a series of steps. As a result, the defects 51 can be removed with higher accuracy, and the alignment of the irradiation positions of the laser light La is unnecessary. Therefore, the defects 51 can be efficiently removed.

In the removal step, in a case where the laser light La is emitted to the defects 51, in order to prevent contamination of the condenser lens 26, the shutter 27 is disposed in front of the condenser lens 26. However, the present invention is not limited to this configuration. The shutter 27 does not need to be disposed in front of the condenser lens 26. However, from the viewpoints of preventing contamination of the condenser lens 26 and suppressing a decrease in defect detection accuracy, it is preferable that the shutter 27 is disposed in front of the condenser lens 26 in a case where the laser light La is emitted to the defects 51.

In addition, it is preferable that, in the removal step, the defects 51 are removed in a state where the carrier gas is supplied to the surface 50a of the semiconductor substrate 50. As a result, as described above, the evaporant 51a (refer to FIG. 3) formed by ablating the defects 51 is removed by the carrier gas from the surface 50a of the semiconductor substrate 50, and the evaporant 51a is prevented from being attached to the condenser lens 26. In addition, reattachment of the evaporant 51a (refer to FIG. 3) to the surface 50a of the semiconductor substrate 50 is also suppressed.

After identifying the positions of the defects 51 on the surface 50a of the semiconductor substrate 50 as shown in FIG. 2, each of the defects 51 may be irradiated with the laser light La to remove the defects 51. That is, the defects 51 may also be removed based on mapping information. In this case, the defects 51 are moved to the irradiation positions of the laser light La, for example, using the stage 22 based on the mapping information. In addition, in the defect removal device 10, the defects 51 can also be removed based on the mapping information shown in FIG. 2 obtained by measuring the defects 51 on the surface 50a of the semiconductor substrate 50 using another device different from the defect removal device 10, for example, using a surface defect measuring device. In this case, the surface defect measurement unit 15 and the detection step are unnecessary, and the adjustment of the optical axes of the incidence light Ls and the laser light La is also unnecessary.

In a case where the container unit 39 (refer to FIG. 3) is used, it is preferable that the defect removal method includes a step of cleaning the inside of the container unit 39. In the cleaning step, specifically, before transporting the semiconductor substrate 50 into the container unit 39, the carrier gas is supplied to the container unit 39, the container unit 39 is heated using a heater, and the flushing process is performed. In the cleaning step, for example, foreign matter such as an ablation attachment or adsorption gas in the container unit 39 is removed.

The present invention is not limited to the defect removal device 10 shown in FIG. 1, and a defect removal device described below can also be used.

### Second Example of Defect Removal Device

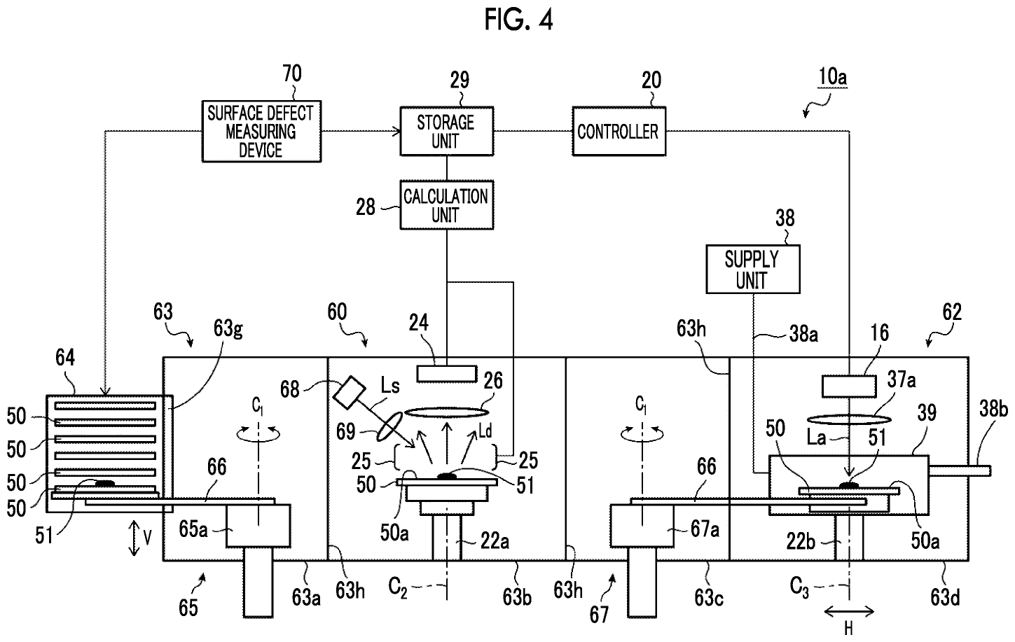

FIG. 4 is a schematic diagram showing a second example of the defect removal device according to the embodiment of the present invention. In the defect removal device 10a shown in FIG. 4, the same structures as those of the defect removal device 10 shown in FIG. 1 will be represented by the same reference numerals, and the detailed description thereof will not be repeated.

A defect removal device 10a shown in FIG. 4 includes a surface defect measurement unit 60 and a removal unit 62 described below in detail.

As in the defect removal device 10 shown in FIG. 1, the defect removal device 10a uses the semiconductor substrate 50 as a measurement target, measures whether or not the defects are present on the semiconductor substrate, and removes the defects on the semiconductor substrate.

The defect removal device 10a includes a first transport chamber 63a, a measurement chamber 63b, a second transport chamber 63c, and a removal chamber 63d, and the first transport chamber 63a, the measurement chamber 63b, the second transport chamber 63c, and the removal chamber 63d are continuously disposed in this order. The first transport chamber 63a, the measurement chamber 63b, the second transport chamber 63c, and the removal chamber 63d are partitioned by a wall 63h. A door (not shown) or the like may be provided such that the semiconductor substrate 50 as a measurement target is movable, and the door may be opened during passage of the semiconductor substrate 50.

In the defect removal device 10a, the semiconductor substrate 50 is transported from the outside of the defect removal device 10a to the first transport chamber 63a and is transported from the first transport chamber 63a to the measurement chamber 63b to measure surface defects of the semiconductor substrate 50 in the measurement chamber 63b. Next, the semiconductor substrate 50 where the surface defects are measured is transported from the measurement chamber 63b to the second transport chamber 63c and is further transported to the removal chamber 63d such that the surface defects of the semiconductor substrate 50 are removed by the removal unit 62 based on the measurement result of whether or not the defects are present on the surface 50a of the semiconductor substrate 50 in the surface defect measurement unit 60.

In the defect removal device 10a, in order to prevent the semiconductor substrate 50 from being exposed to outside air, the first transport chamber 63a, the measurement chamber 63b, the second transport chamber 63c, and the removal chamber 63d can be made to be in a specific atmosphere. For example, a vacuum pump may be provided to discharge gas in the first transport chamber 63a, the measurement chamber 63b, the second transport chamber 63c, and the removal chamber 63d such that the inside thereof is in a reduced pressure atmosphere. In addition, inert gas such as nitrogen gas may be supplied to the first transport chamber 63a, the measurement chamber 63b, the second transport chamber 63c, and the removal chamber 63d such that the inside thereof is in an inert gas atmosphere.

In the first transport chamber 63a, the semiconductor substrate 50 transported from the outside of the defect removal device 10a is transported to the measurement chamber 63b. In the first transport chamber 63a, an introduction unit 63g is provided on a side surface. A storage container 64 is provided in the introduction unit 63g. In the introduction unit 63g, a sealing member (not shown) is provided to maintain airtightness with the storage container 64.

In the storage container 64, for example, a plurality of semiconductor substrates 50 are disposed and stored in the form of shelves. The semiconductor substrate 50 is, for example, a disk-shaped substrate.

The storage container 64 is, for example, FOUP. By using the storage container 64, the semiconductor substrates 50 can be transported to the defect removal device 10a in a state where they are sealed without being exposed to outside air. As a result, contamination of the semiconductor substrate 50 can be suppressed.

In the first transport chamber 63a, a transport device 65 is provided. The transport device 65 transports the semiconductor substrate 50 in the storage container 64 from the first transport chamber 63a to the measurement chamber 63b adjacent thereto.

The transport device 65 is not particularly limited as long as it can take out the semiconductor substrate 50 from the storage container 64 and transport the semiconductor substrate 50 to a stage 22a of the measurement chamber 63b.

The transport device 65 shown in FIG. 4 includes: a transport arm 66 where the outer side of the semiconductor substrate 50 is sandwiched; and a driving unit (not shown) that drives the transport arm 66. The transport arm 66 is attached to an attachment unit 65a and is rotatable around a rotation axis C₁. The transport arm 66 is not particularly limited to the configuration where the outer side of the semiconductor substrate 50 is sandwiched as long as it can hold and transport the semiconductor substrate 50. A device used for transport between processes of semiconductor wafers can be appropriately used.

In the transport device 65, the attachment unit 65a is movable in the height direction V, and the transport arm 66 is movable in the height direction V as a direction parallel to the rotation axis C₁. By the attachment unit 65a moving in the height direction V, the position of the transport arm 66 in the height direction V can be changed.

(Surface Defect Measurement Unit)

In the measurement chamber 63b, the surface defects of the semiconductor substrate 50 are measured as described above. In the measurement chamber 63b, the surface defect measurement unit 60 is provided.

The surface defect measurement unit 60 measures whether or not the defects are present on the surface 50a of the semiconductor substrate 50 and obtains the position information of the defects on the surface 50a of the semiconductor substrate 50.

The surface defect measurement unit 60 includes: the stage 22a on which the semiconductor substrate 50 is placed; an incidence unit 68 that irradiates the surface 50a of the semiconductor substrate 50 with the incidence light Ls; and a condenser lens 69 that collects the incidence light Ls to the surface 50a of the semiconductor substrate 50.

The stage 22a on which the semiconductor substrate 50 is placed is rotatable around a rotation axis C₂, can change a position of the semiconductor substrate 50 in a height direction V, and can change a position of the semiconductor substrate 50 in a direction H orthogonal to the height direction V.

The irradiation position of the incidence light Ls on the surface 50a of the semiconductor substrate 50 can be changed by the stage 22a. As a result, a specific region or the entire region of the surface 50a of the semiconductor substrate 50 can be sequentially irradiated with the incidence light Ls to detect the defects such as foreign matter on the surface 50a of the semiconductor substrate 50.

Since the incidence unit 68 has the same configuration as that of the first light source unit 12, the detailed description thereof will not be repeated.

Regarding an incidence angle of the incidence light Ls, it is assumed that all directions parallel to the surface 50a of the semiconductor substrate 50 are 0° and a direction perpendicular to the surface 50a of the semiconductor substrate 50 is 90°. At this time, in a case where the incidence angle of the incidence light Ls is defined as a range from minimum 0° to maximum 90°, the incidence angle of the incidence light Ls is 0° or more and 900 or less and preferably more than 0° and less than 90°.

The surface defect measurement unit 60 includes a light receiving unit that receives the radiated light Ld radiated by reflection or scattering of the incidence light Ls from the surface 50a of the semiconductor substrate 50. The surface defect measurement unit 60 shown in FIG. 4 includes, for example, two light receiving units 24 and 25. In a case where any one of the light receiving units 24 and 25 receives the radiated light Ld, it is determined that the defects are present on the surface 50a of the semiconductor substrate 50. In a case where the radiated light is not generated, it is determined that the defects are not present on the surface 50a of the semiconductor substrate 50. This way, whether or not the defects are present on the surface 50a of the semiconductor substrate 50 is measured.

The light receiving unit 25 is disposed around the semiconductor substrate 50. The light receiving unit 24 is disposed above the surface 50a of the semiconductor substrate 50. The condenser lens 26 is provided between the surface 50a of the semiconductor substrate 50 and the light receiving unit 24. The radiated light generated from the incidence light Ls is collected to the light receiving unit 24 by the condenser lens 26. The radiated light can be efficiently collected to the light receiving unit 24 by the condenser lens 26. The number of the light receiving units is not particularly limited to 2. The surface defect measurement unit 60 may be configured to include any one of the light receiving unit 25 or the light receiving unit 24 or may be configured to include three or more light receiving units.

The light receiving unit 25 receives the radiated light on a low angle side. The light receiving on the low angle side refers to the light receiving in a range of 0° or more and 800 or less at the above-described incidence angle.

The light receiving unit 24 receives the radiated light on a high angle side. The light receiving on the high angle side refers to the light receiving in a range of more than 800 and 900 or less at the above-described incidence angle.

Since the configurations of the light receiving unit 25 and the light receiving unit 24 are as described above, the detailed description thereof will not be repeated.

The surface defect measurement unit 60 includes the calculation unit 28 and the storage unit 29. In addition, since the calculation unit 28 and the storage unit 29 are as described above, the detailed description thereof will not be repeated.

The light receiving units 24 and 25 receive the radiated light Ld radiated by reflection or scattering of the incidence light Ls irradiated from the incidence unit 68 from the defects on the surface 50a of the semiconductor substrate 50. As described above, in the light receiving units 24 and 25, the radiated light is detected as bright spots. The calculation unit 28 calculates the sizes of the defects that cause the bright spots, that is, the detection sizes based on the sizes of standard particles among the sizes of the bright spots including the information of the radiated light from the defects received by the light receiving units 24 and 25. The calculation of the detection sizes based on the sizes of the standard particles is performed using a calculation device in a commercially available surface inspection device or using a well-known calculation method. The calculation unit 28 acquires position information regarding an irradiation position of the incidence light Ls from the controller 20, and the light receiving units 24 and 25 obtains the position information of the defects on the surface 50a of the semiconductor substrate 50 and the information regarding the sizes of the defects based on the information regarding the radiated light from the defects. The obtained position information of the defects on the surface 50a of the semiconductor substrate 50 and the obtained information regarding the sizes of the defects are stored in the storage unit 29.

Here, in the surface defect measurement unit 60, the stage 22a and the incidence unit 68 are controlled by the controller 20. In addition, the calculation unit 28 is also controlled by the controller 20.

The controller 20 acquires the position information of the incidence light Ls irradiated from the incidence unit 68 on the surface 50a of the semiconductor substrate 50. In order to irradiate a region that is not irradiated with the incidence light Ls on the surface 50a of the semiconductor substrate 50 with the incidence light Ls, the controller 20 drives the stage 22a and changes the irradiation position of the surface 50a of the semiconductor substrate 50.

Further, in the surface defect measurement unit 60, the entire region of the surface 50a of the semiconductor substrate 50 is irradiated with the incidence light Ls, and the position information of the defect on the surface 50a of the semiconductor substrate 50 and the information regarding the size of the defect at each of the irradiation positions is obtained based on the information regarding the radiated light received by the light receiving units 24 and 25. As a result, the position information of the defects on the entire surface 50a of the semiconductor substrate 50 and the information regarding the sizes of the defects can be obtained. That is, the two-dimensional position information of the defects on the surface 50a of the semiconductor substrate 50 and the information regarding the sizes of the defects can be obtained.

During the measurement of the surface defect measurement unit 60, the atmosphere of the measurement chamber 63b is not particularly limited and may be a reduced pressure atmosphere or a nitrogen gas atmosphere.

As the surface defect measurement unit 60, for example, a surface inspection device (Surfscan SP5; manufactured by KLA Corporation) can be used.

In the second transport chamber 63c, a transport device 67 is provided. The transport device 67 transports the semiconductor substrate 50 where the surface defects are measured by the surface defect measurement unit 60 in the measurement chamber 63b from the measurement chamber 63b to the removal chamber 63d.

As the transport device 67, a transport device having the same configuration as the transport device 65 can be used. The transport device 67 includes: the transport arm 66 where the outer side of the semiconductor substrate 50 is sandwiched; and the driving unit (not shown) that drives the transport arm 66. The transport arm 66 is attached to an attachment unit 67a and is rotatable around the rotation axis C₁.

In the transport device 67, the attachment unit 67a is movable in the height direction V, and the transport arm 66 is movable in the height direction V as a direction parallel to the rotation axis C₁. By the attachment unit 67a attached to the transport arm 66 moving in the height direction V, the position of the transport arm 66 in the height direction V can be changed.

(Removal Unit)

In the removal chamber 63d, the removal unit 62 is provided. The removal unit 62 irradiates the surface 50a of the semiconductor substrate 50 with the laser light La to remove the defects 51.

The removal unit 62 includes: a stage 22b on which the semiconductor substrate 50 is placed; and the container unit 39 that stores the semiconductor substrate 50 placed on the stage 22b.

The stage 22b on which the semiconductor substrate 50 is placed is rotatable around a rotation axis C₃, can change a position of the semiconductor substrate 50 in a height direction V, and can change a position of the semiconductor substrate 50 in a direction H orthogonal to the height direction V.

The stage 22b is controlled by the controller 20. In order to irradiate the defects 51 on the surface 50a of the semiconductor substrate 50 with laser light La, the controller 20 drives the stage 22b to change the irradiation position of the surface 50a of the semiconductor substrate 50.

The removal unit 62 includes the second light source 16 that irradiates the defects 51 on the surface 50a of the semiconductor substrate 50 measured by the surface defect measurement unit 60 with the laser light La. A condenser lens 37a that collects the laser light La to the defects 51 on the surface 50a of the semiconductor substrate 50 is provided between the second light source 16 and the surface 50a of the semiconductor substrate 50.

The second light source 16 and the condenser lens 37a are provided outside the container unit 39. In the container unit 39, a window portion (not shown) through which the laser light La can transmit is provided such that the laser light La enters the container unit 39.

The removal unit 62 includes the supply unit 38 that supplies carrier gas to the container unit 39. The supply unit 38 is connected to the container unit 39 through the pipe 38a.

In addition, the outlet unit 38b that causes the carrier gas to flow out from the container unit 39 to the outside is provided in the container unit 39. The outlet unit 38b can cause the carrier gas to flow out from the container unit 39 to the outside. Since the container unit 39, the outlet unit 38b, and the carrier gas are as described above, the detailed description thereof will not be repeated.

The defect removal device 10a shown in FIG. 4 includes the controller 20, and the controller 20 drives the stage 22b of the removal unit 62 or changes the irradiation position of the laser light La to irradiate the defects 51 on the surface 50a of the semiconductor substrate 50 with the laser light La based on the position information of the detected defects such as foreign matter on the surface 50a of the semiconductor substrate 50 and the information regarding the sizes that are stored in the storage unit 29 of the surface defect measurement unit 60. As a result, the defects 51 of the semiconductor substrate 50 can be removed with high accuracy.

In addition, in the defect removal device 10a, the defects 51 on the surface 50a of the semiconductor substrate 50 can be removed by the removal unit 62 in a state where the entire semiconductor substrate 50 is stored in the container unit 39.

### Second Example of Defect Removal Method

The defect removal method includes: a step of measuring whether or not the defect is present on the semiconductor substrate to obtain the position information of the defect on the semiconductor substrate; and a removal step of irradiating the semiconductor substrate with laser light to remove the defect based on the position information of the defect on the semiconductor substrate. Hereinafter, the defect removal method will be specifically described.

In the defect removal method, for example, the storage container 64 in which a plurality of semiconductor substrates 50 are stored is connected to the introduction unit 63g on the side surface of the first transport chamber 63a of the defect removal device 10a shown in FIG. 4. By opening a lid of the storage container 64, the defect removal device 10a enters a state where the semiconductor substrate 50 can be taken out from the storage container 64.

Next, using the transport device 65 of the first transport chamber 63a, the semiconductor substrate 50 is taken out from the storage container 64, and the semiconductor substrate 50 is transported to the stage 22a of the measurement chamber 63b. Through the step of transporting the semiconductor substrate 50 from the storage container 64 to the stage 22a of the measurement chamber 63b, even in a case where the semiconductor substrate 50 is transported from the outside of the defect removal device 10a, contamination of the semiconductor substrate 50 is suppressed. In a state where contamination of the semiconductor substrate 50 is suppressed, the surface defects of the semiconductor substrate 50 can be measured by the surface defect measurement unit 60.

Next, in the measurement chamber 63b, the surface 50a of the semiconductor substrate 50 is irradiated with the incidence light Ls from the incidence unit 68 of the surface defect measurement unit 60 to measure the surface defects of the semiconductor substrate 50. As a result, the position information of the defects such as foreign matter on the surface 50a of the semiconductor substrate 50 and the sizes of the defects are detected. For example, mapping information representing the defects 51 on the surface 50a of the semiconductor substrate 50 as shown in FIG. 2 is obtained.

Next, the transport device 67 of the second transport chamber 63c shown in FIG. 4 transports the semiconductor substrate 50 where the surface defects are measured from the measurement chamber 63b to the removal chamber 63d.

Next, in the removal chamber 63d, the removal unit 62 removes the defects 51 based on the position information of the defects 51 on the surface 50a of the semiconductor substrate 50 and the information regarding the sizes, that is, the mapping information. The removal of the defects 51 is performed, for example, in a state where the entire semiconductor substrate 50 is stored in the container unit 39 and a state where the carrier gas is supplied from the supply unit 38 to the container unit 39. During the removal, the positions of the defects 51 are identified based on the mapping information, and the semiconductor substrate 50 is moved to move the defects 51 to the irradiation position of the laser light La, for example, using the stage 22b.

Next, the defects 51 on the surface 50a of the semiconductor substrate 50 are irradiated with the laser light La from the second light source 16 to remove the defects 51. As a result, the defects 51 of the semiconductor substrate 50 can be removed with high accuracy.

In the defect removal method, the inside of the container unit 39 may be cleaned using the carrier gas before the removal step. In the cleaning step, specifically, before transporting the semiconductor substrate 50 into the container unit 39, the carrier gas is supplied to the container unit 39, the container unit 39 is heated using a heater, and the flushing process is performed. In the cleaning step, for example, foreign matter such as an ablation attachment or adsorption gas in the container unit 39 is removed.

The container unit 39 is provided in the removal unit 62. However, the present invention is not limited to this configuration, and the removal unit 62 may be configured not to include the container unit 39.

Next, in the defect removal device 10a, the surface defects of the semiconductor substrate 50 are measured by the surface defect measurement unit 60. However, the present invention is not limited to this configuration. The surface defect measurement unit 60 is not particularly limited to the configuration shown in FIG. 4.

Using another device different from the surface defect measurement unit 60, for example, using a surface defect measuring device 70, the defects 51 on the surface 50a of the semiconductor substrate 50 may be measured to acquire the mapping information shown in FIG. 2. In this case, the mapping information acquired by the surface defect measuring device 70 is supplied to the storage unit 29.

The semiconductor substrate 50 where the defects 51 are measured by the surface defect measuring device 70 is transported to the defect removal device 10a, for example, using the storage container 64. The semiconductor substrate 50 is transported to the removal chamber 63d through the first transport chamber 63a, the measurement chamber 63b, and the second transport chamber 63c.

Next, the controller 20 reads the mapping information from the storage unit 29 and identifies the positions of the defects 51 on the surface 50a of the semiconductor substrate 50 based on the mapping information. Next, the controller 20 controls the removal unit 62 such that the semiconductor substrate 50 is moved to move the defects 51 to the irradiation position of the laser light La using the stage 22b. Next, the defects 51 on the surface 50a of the semiconductor substrate 50 are irradiated with the laser light La from the second light source 16 to remove the defects 51. Even in this case, the defects 51 of the semiconductor substrate 50 can be removed with high accuracy. For example, the removal of the defects 51 is performed in a state where the carrier gas is supplied.

As described above, in a case where the mapping information obtained by the measurement using the device other than the defect removal device 10a, for example, using the surface defect measuring device 70 is used, the surface defect measurement unit 60 does not need to be provided in the defect removal device 10a, and the defect removal device 10a may be configured not to include the surface defect measurement unit 60. In this case, the defect removal device 10a is configured to include only the removal unit 62.

### Third Example of Defect Removal Device

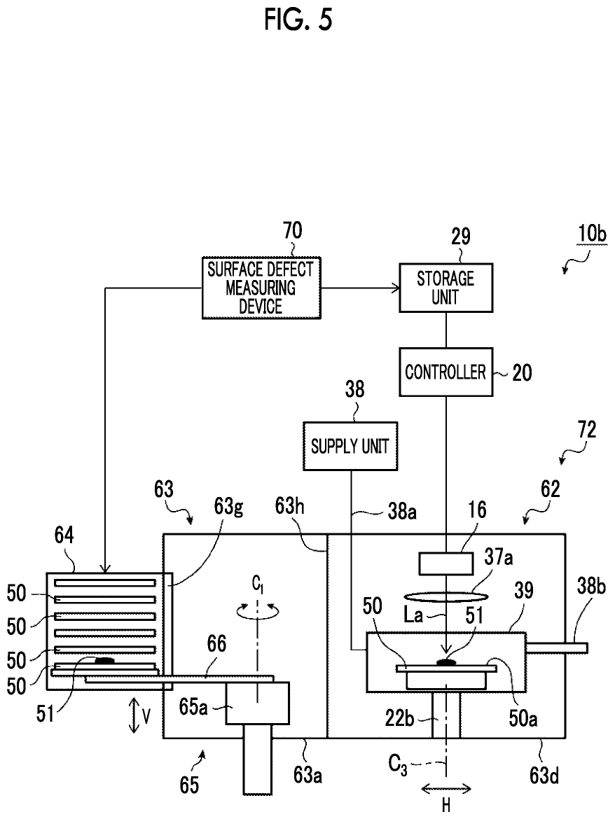

Further, as shown in FIG. 5, a removal device 72 may be used instead of the removal unit 62, and a defect removal device 10b including the above-described surface defect measuring device 70 and the removal device 72 may be used. The removal device 72 includes the above-described removal unit 62.

In the defect removal device 10b, the surface defect measuring device 70 and the removal device 72 are separate devices and are not integrated. Therefore, in the defect removal device 10b, the semiconductor substrate 50 where the defects 51 of the surface 50a are measured by the surface defect measuring device 70 is transported to the removal device 72 stored, for example, in the storage container 64. In the removal device 72, the semiconductor substrate 50 is taken out from the storage container 64 and is placed on the stage 22b. The removal device 72 irradiates the defects 51 with the laser light La to remove the defects 51 based on the mapping information. Even in this case, the defects 51 of the semiconductor substrate 50 can be removed with high accuracy. For example, the removal of the defects 51 is performed in a state where the carrier gas is supplied.

FIG. 5 is a schematic diagram showing the third example of the defect removal device according to the embodiment of the present invention. In the defect removal device 10b shown in FIG. 5, the same structures as those of the defect removal device 10a shown in FIG. 4 will be represented by the same reference numerals, and the detailed description thereof will not be repeated.

(Semiconductor Substrate)

The semiconductor substrate is not particularly limited, and various semiconductor substrates such as a silicon (Si) substrate, a sapphire substrate, a SiC substrate, a GaP substrate, a GaAs substrate, an InP substrate, or a GaN substrate can be used. As the semiconductor substrate, a silicon semiconductor substrate is widely used.

[Pattern Forming Method and Method of Manufacturing Electronic Device]

A pattern is formed on the semiconductor substrate 50 from which foreign matter is removed using the above-described defect removal method. In the pattern forming method, the pattern can be formed using a well-known manufacturing process of pattern formation, except that the semiconductor substrate from which the defects are removed using the above-described defect removal method is used.

The pattern forming method includes: a step of forming a resist film on the surface of the semiconductor substrate; and a step of forming a pattern on the resist film. As the resist film, a resist film that is used in a manufacturing process of a semiconductor element can be appropriately used. In addition, a photolithography method that is used in a manufacturing process of a semiconductor element can be appropriately used.

As the pattern forming method, a general lithography method can be used. For example, the resist pattern is exposed and developed by lithography, for example, using an extreme ultraviolet (EUV), ArF, or KrF laser as a light source. In a case where the resist film is a positive tone, the exposed portion can be dissolved to obtain the resist pattern. In a case where the resist film is a negative tone, the non-exposed portion can be dissolved to obtain the resist pattern.

In addition, an electronic device is formed on the semiconductor substrate 50 from which foreign matter is removed using the above-described defect removal method. In order to manufacture the electronic device, a photolithography method is used.

The method of manufacturing an electronic device includes: a step of forming a resist film on the surface of the semiconductor substrate; and a step of forming a pattern of an electronic device on the resist film. Further, a step of forming an electronic device on the semiconductor substrate based on the pattern of the electronic device may be provided. In the method of manufacturing an electronic device, the electronic device can be manufactured using a well-known manufacturing process of an electronic device, except that the semiconductor substrate from which the defects are removed using the above-described defect removal method is used.

The pattern of the electronic device varies depending on an electronic device to be formed. In addition, the pattern of the electronic device includes a pattern of an element forming an electronic device such as a transistor or an inductor. Examples of the electronic device are as follows.

(Electronic Device) Examples of the electronic device include a logic large scale integration (LSI) (for example, an application specific integrated circuit (ASIC), a field programmable gate array (FPGA), or an application specific standard product (ASSP)), a microprocessor (for example, a central processing unit (CPU) or a graphics processing unit (GPU)), a memory (for example, a dynamic random access memory (DRAM), a hybrid memory cube (HMC), a magnetic RAM (MRAM), a phase-change memory (PCM), a resistive RAM (ReRAM), a ferroelectric RAM (FeRAM), or a flash memory (NAND (Not AND) flash)), a light emitting diode (LED) (for example, a microflash of portable terminal, a vehicle-mounted LED, a projector light source, a LCD backlight, or a general lighting device), a power device, an analog integrated circuit (IC) (for example, a direct current (DC)-direct current (DC) converter or an insulated gate bipolar transistor (IGBT)), micro electromechanical systems (MEMS) (for example, an acceleration sensor, a pressure sensor, an oscillator, or a gyro sensor), a wireless device (for example, a global positioning system (GPS), a frequency modulation (FM), a near field communication (NFC), a RF expansion module (RFEM), a monolithic microwave integrated circuit (MMIC), or a wireless local area network (WLAN)), a discrete element, a back side illumination (BSI), a contact image sensor (CIS), a camera module, a complementary metal oxide semiconductor (CMOS), a passive device, a surface acoustic wave (SAW) filter, a radio frequency (RF) filter, a radio frequency integrated passive device (RFIPD), and a broadband (BB).

Basically, the present invention is configured as described above. Hereinabove, the defect removal device, the defect removal method, the pattern forming method, and the method of manufacturing an electronic device according to the embodiment of the present invention has been described in detail. However, the present invention is not limited to the above-described examples, and various improvements or modifications may be made within a range not departing from the scope of the present invention.

### EXAMPLES

The present invention will be described in more detail based on the following examples. Materials, used amounts, ratios, treatment details, treatment procedures, and the like shown in the following examples can be appropriately changed within a range not departing from the scope of the present invention. Accordingly, the scope of the present invention is not limited to the following examples.

Hereinafter, Examples 1 to 4 will be described.

### Example 1 and 2

In Examples 1 and 2, a dispersion liquid including Fe nanoparticles having a particle diameter of 10 to 100 nm was prepared. The dispersion liquid was diluted and adjusted such that the number of the particles in a silicon substrate having a diameter of 300 mm was 1 particles/cm². Using an electrostatic spray device, the adjusted dispersion liquid was applied to the silicon substrate having a diameter of 300 mm.

The particle diameters of the Fe nanoparticles having a particle diameter of 10 to 100 nm are values obtained as follows.

Another silicon substrate was prepared separately from the above-described silicon substrate, a dispersion liquid including nanoparticles was applied to the silicon substrate, and the particle diameters were measured using an optical defect inspection device SP7 (manufactured by KLA Corporation). In addition, in a case where particles having a desired particle diameter were not able to be detected due to the resolution of a measuring device or the like, the sizes were defined using a method described in paragraphs “0015” to “0067” of JP2009-188333A. That is, a SiOₓ layer was formed on the substrate using a chemical vapor deposition (CVD) method, and subsequently, a dispersion liquid layer including nanoparticles was formed to cover the SiOₓ layer. Next, the following method was used, in which a composite layer including the SiOₓ layer and the dispersion liquid layer applied to the SiOₓ layer was dry-etched to obtain protrusions, the obtained protrusions were irradiated with light to detect scattered light, the volumes of the protrusion were calculated from the scattered light, and the particle diameters of the Fe nanoparticles were calculated from the volumes of the protrusions.

In order to grasp the number of defects on the silicon substrate before the defect removal using the defect removal device 10 shown in FIG. 1, the silicon substrate was irradiated with incidence light to measure the number of the defects using the defect removal device 10 shown in FIG. 1.

During the defect removal using the defect removal device 10 shown in FIG. 1, the optical axes of the incidence light Ls and the laser light La were aligned in advance. As the incidence light, a continuous wave was used. As the laser light, a pulsed wave was used, and a femtosecond laser was used.

Next, the defects were detected using the incidence light, and the positions of the defects on the silicon substrate and the sizes were acquired and stored in the storage unit. Among the plurality of defects, one defect was selected. In Example 1, the size of the selected defect was 14.5 nm. The size of the selected defect is shown in the column “Selected Defect” of Table 1 below.

Next, in the silicon substrate where the defects were measured, the selected defect was irradiated with the laser light to remove the defect. The result of the defect removal is shown in the column “Defect Inspection Result after Defect Removal” of Table 1 below.

Next, the defects on the silicon substrate were measured again using the incidence light, and whether or not the selected defect on the silicon substrate is removed was checked.

In Example 1, the defect was removed in a state where carrier gas was supplied to the surface of the semiconductor substrate.

In Example 1, argon gas was used as the carrier gas. The flow rate of the carrier gas was 8.45×10⁻² Pa·m³/sec (50 sccm).

In Example 2, the defect was removed in a state where carrier gas was not supplied to the surface of the semiconductor substrate. In Example 2, one defect was selected. The size of the selected defect was 15.1 nm. The size of the selected defect is shown in the column “Selected Defect” of Table 1 below. In addition, the result of the defect removal is shown in the column “Defect Inspection Result after Defect Removal” of Table 1 below.

TABLE 1

| | Number of | | | |
|---|---|---|---|---|
| | Defects on | | | Defect |
| | Silicon | | | Inspection |
| | Substrate | | | Result |
| | (Before Defect | Supply of | Selected | after Defect |
| | Removal) | Carrier Gas | Defect | Removal |
| Example 1 | 716 | Supplied | 14.5 nm | Not Detected |
| Example 2 | 699 | Not Supplied | 15.1 nm | Not Detected |

As shown in Table 1, in both of Examples 1 and 2, the selected defect was able to be removed.

In Example 1 where the carrier gas was supplied during the removal of the defect, it was verified that attachment of an ablation product or the like in the chamber was able to be prevented and the fine nanoparticles were able to be dry-cleaned.

In Example 2, it was verified that the selected defect was able to be removed and the fine nanoparticles were able to be dry-cleaned. In Example 2, the carrier gas was not supplied, and thus attachment of an ablation product or the like in the chamber was observed.

### Examples 3 and 4

In Example 3, a dispersion liquid including Fe nanoparticles having a particle diameter of 10 to 200 nm was prepared. The dispersion liquid was diluted and adjusted such that the number of the particles in a silicon substrate having a diameter of 300 mm was 1 particles/cm². Using an electrostatic spray device, the adjusted dispersion liquid was applied to the silicon substrate having a diameter of 300 mm.

The particle diameters of the Fe nanoparticles having a particle diameter of 10 to 200 nm according to Example 3 are values obtained using the same method as that of the particle diameters of the Fe nanoparticles having a particle diameter of 10 to 100 nm according to Examples 1 and 2.

The defect removal device 10 shown in FIG. 1 was used. The optical axes of the incidence light Ls and the laser light La were aligned in advance. As the incidence light, a continuous wave was used. As the laser light, a pulsed wave was used, and a femtosecond laser was used.

The defects were detected using the incidence light, and the positions of the defects on the silicon substrate and the sizes were acquired and stored in the storage unit.

Next, in a state where the carrier gas was supplied to the silicon substrate where the defects were measured, the defect was irradiated with the laser light to remove the defect. During the removal of the defect, the shutter was disposed in front of the condenser lens.

Next, the defect was irradiated with the incidence light to check whether or not the defect was removed.

Argon gas was used as the carrier gas. The flow rate of the carrier gas was 8.45×10⁻² Pa·m³/sec (50 sccm).

The removal of the defect and the check of whether or not the defect was removed were performed on all of the defects.

The removal of the defect and the check of whether or not the defect was removed were performed on 100 batches of silicon substrates. One batch include 25 silicon substrates.

In Example 3, after performing the removal of the defect and the check of whether or not the defect was removed on 10 batches, and a dispersion liquid including Fe nanoparticles having a particle diameter of 20 nm was prepared. The dispersion liquid was diluted and adjusted such that the number of the particles in a silicon substrate having a diameter of 300 mm was 1 particles/cm².

In order to measure the particle diameter of the Fe nanoparticles having a particle diameter of 20 nm according to Example 3, another silicon substrate was prepared separately from the above-described silicon substrate, a dispersion liquid including nanoparticles was applied to the silicon substrate, and the particle diameters were measured using an optical defect inspection device SP7 (manufactured by KLA Corporation).

Next, the defects having a particle diameter of 20 nm on the silicon substrate were measured using the incidence light. In Example 3, it was verified that the defects having a particle diameter of 20 nm were able to be measured.

Further, after performing the removal of the defect and the check of whether or not the defect was removed on 100 batches, and a dispersion liquid including Fe nanoparticles having a particle diameter of 20 nm was prepared. The dispersion liquid was diluted and adjusted such that the number of the particles in a silicon substrate having a diameter of 300 mm was 1 particles/cm².

Next, the defects having a particle diameter of 20 nm on the silicon substrate were measured using the incidence light. In Example 3, it was verified that the defects having a particle diameter of 20 nm were able to be measured.

In Example 4, as compared to Example 3, the shutter was not disposed in front of the condenser lens during the removal of the defect. That is, Example 4 was the same as Example 3, except that the shutter was not closed.

Even in Example 4, after performing the removal of the defect and the check of whether or not the defect was removed on 10 batches and 100 batches, and a dispersion liquid including Fe nanoparticles having a particle diameter of 20 nm was prepared. The dispersion liquid was diluted and adjusted such that the number of the particles in a silicon substrate having a diameter of 300 mm was 1 particles/cm².

In order to measure the particle diameter of the Fe nanoparticles having a particle diameter of 20 nm according to Example 4, using the same method as that of the particle diameters of the Fe nanoparticles having a particle diameter of 20 nm according to Example 3, another silicon substrate was prepared separately from the above-described silicon substrate, a dispersion liquid including nanoparticles was applied to the silicon substrate, and the particle diameters were measured using an optical defect inspection device SP7 (manufactured by KLA Corporation).

Next, the defects having a particle diameter of 20 nm on the silicon substrate were measured using the incidence light. In Example 4, it was verified that the defects having a particle diameter of 20 nm were not able to be measured.

TABLE 2

| | | Detection | Detection |
|---|---|---|---|
| | | of Defects | of Defects |
| | | having Diameter | having Diameter |
| | | of 20 nm | of 20 nm after |
| | | after Processing | Processing 100 |
| | Shutter | 10 Batches | Batches |
| Example 3 | Provided | Detectable | Detectable |
| Example 4 | Not | Detectable | Not Detectable |
| | Provided | | |

As shown in Table 2, in both of Examples 3 and 4, defects having a diameter of 20 nm, that is, nanoparticles were able to be detected in 10 batches.

Even in a case where a large number of batches such as 100 batches were processed, in Example 3 where the condenser lens was protected using the shutter, defects having a diameter of 20 nm were able to be detected.

### EXPLANATION OF REFERENCES

10, 10a, 10b: defect removal device
11: chamber
12: first light source unit
14: detection unit
16: second light source
18: alignment unit
20: controller
22, 22a, 22b: stage
24, 25: light receiving unit
26: condenser lens
27: shutter
28: calculation unit
29: storage unit
30: first mirror
30a: mirror
30b: mirror
32: optical element
32a: first incident surface
32b: emission surface
32c: second incident surface
32d: surface
32e: transmitting reflecting surface
34: second mirror
34a: mirror
34b: mirror
36: photodetector
37: condenser lens
38: supply unit
38a: pipe
38b: outlet unit
39: container unit
50: semiconductor substrate
50a: surface
51: defect
51a: evaporant
60: surface defect measurement unit
62: removal unit
63a: first transport chamber
63b: measurement chamber
63c: second transport chamber
63d: removal chamber
63g: introduction unit
63h: wall
64: storage container
65: transport device
65a: attachment unit
66: transport arm
67: transport device
67a: attachment unit
68: incidence unit
69: condenser lens
70: surface defect measuring device
72: removal device
C, C₁, C₂, C₃: rotation axis
H: direction
La: laser light
La1: second separated light
Ld: radiated light
Ls: incidence light
Ls1: first separated light
V: height direction

What is claimed is:

1. A defect removal device using position information of a defect on a semiconductor substrate, the defect removal device comprising:
a removal unit that irradiates the semiconductor substrate with laser light to remove the defect based on the position information of the defect on the semiconductor substrate.

2. The defect removal device according to claim 1, further comprising:
a surface defect measurement unit that measures whether or not the defect is present on the semiconductor substrate to obtain the position information of the defect on the semiconductor substrate.

3. A defect removal device comprising:
a surface defect measuring device that measures whether or not a defect is present on a semiconductor substrate to obtain position information of the defect on the semiconductor substrate; and
a removal device that irradiates the semiconductor substrate with laser light to remove the defect based on the position information of the defect on the semiconductor substrate obtained by the surface defect measuring device.

4. A defect removal device comprising:
a surface defect measurement unit including a first light source unit and a detection unit,
in which the first light source unit emits incidence light for detecting a defect on a semiconductor substrate and
the detection unit detects the defect on the semiconductor substrate based on radiated light radiated by reflection or scattering of the incidence light from the defect of the semiconductor substrate;
a removal unit that irradiates the semiconductor substrate with laser light to remove the defect; and
an alignment unit that adjusts optical axes of the incidence light and the laser light,
wherein the optical axes of the incidence light and the laser light are adjusted by the alignment unit such that the incidence light and the laser light are emitted to the semiconductor substrate.

5. The defect removal device according to claim 4,
wherein the removal unit emits the laser light to the defect detected by the surface defect measurement unit.

6. The defect removal device according to claim 4,
wherein the optical axes of the incidence light and the laser light are adjusted to be the same by the alignment unit such that the incidence light and the laser light are emitted to the semiconductor substrate.

7. The defect removal device according to claim 4,
wherein the surface defect measurement unit includes a light receiving unit that receives the radiated light and a condenser lens that collects the radiated light to the light receiving unit, and
in a case where the laser light is emitted to the defect, a shutter is disposed between the condenser lens and a surface of the semiconductor substrate.

8. The defect removal device according to claim 4,
wherein the alignment unit includes
an optical element that allows incidence of the incidence light and the laser light, emits the incident incidence light and the incident laser light in the same direction, and separates the incident incidence light and the incident laser light such that first separated light separated from the incidence light and second separated light separated from the laser light are emitted in the same direction,
a first mirror that causes the incidence light to be incident into the optical element,
a second mirror that causes the laser light to be incident into the optical element, and
a photodetector that detects at least an intensity of light for the first separated light of the incidence light and the second separated light of the laser light that are separated by the optical element, and
inclinations of the first mirror and the second mirror are adjustable.

9. The defect removal device according to claim 4,
wherein the surface defect measurement unit obtains position information of the defect on the semiconductor substrate.

10. The defect removal device according to claim 2,
wherein the surface defect measurement unit includes a first light source unit that emits incidence light for detecting the defect on the semiconductor substrate and a light receiving unit that receives radiated light radiated by reflection or scattering of the incidence light from the defect on the semiconductor substrate.

11. The defect removal device according to claim 2,
wherein the surface defect measurement unit includes a storage unit that stores the position information.

12. The defect removal device according to claim 1, further comprising:
a supply unit that supplies carrier gas to a surface of the semiconductor substrate.

13. The defect removal device according to claim 4,
wherein the incidence light is laser light that continuously oscillates.

14. The defect removal device according to claim 1,
wherein the laser light is laser light that pulse-oscillates.

15. A defect removal method using position information of a defect on a semiconductor substrate, the defect removal method comprising:
irradiating the semiconductor substrate with laser light to remove the defect based on the position information of the defect on the semiconductor substrate.

16. A defect removal method using position information of a defect on a semiconductor substrate, the defect removal method comprising:
a step of measuring whether or not the defect is present on the semiconductor substrate to obtain the position information of the defect on the semiconductor substrate; and
a removal step of irradiating the semiconductor substrate with laser light to remove the defect based on the position information of the defect on the semiconductor substrate.

17. A defect removal method comprising
a detection step of emitting incidence light for detecting a defect on a semiconductor substrate to detect the defect on the semiconductor substrate; and
a removal step of emitting laser light of which an optical axis is adjusted to be the same as that of the incidence light to the semiconductor substrate to remove the defect.

18. The defect removal method according to claim 17,
wherein in the removal step, the laser light is emitted to the defect detected in the detection step along the same optical axis as that of the incidence light.

19. The defect removal method according to claim 17, further comprising:
an adjustment step of adjusting the optical axes of the incidence light and the laser light before the detection step or before the removal step.

20. The defect removal method according to claim 17,
wherein in the removal step, the defect is removed in a state where carrier gas is supplied to a surface of the semiconductor substrate.

21. The defect removal method according to claim 17,
wherein in the detection step, the defect on the semiconductor substrate is detected using a light receiving unit that receives radiated light radiated by reflection or scattering of the incidence light from the defect on the semiconductor substrate and a condenser lens that collects the radiated light to the light receiving unit, and
in the removal step, a shutter is disposed between the condenser lens and a surface of the semiconductor substrate such that the laser light is emitted to the detected defect.

22. The defect removal method according to claim 17,
wherein in the detection step, position information of the defect on the semiconductor substrate is obtained.

23. The defect removal method according to claim 17,
wherein the incidence light is laser light that continuously oscillates.

24. The defect removal method according to claim 15,
wherein the laser light is laser light that pulse-oscillates.

25. A pattern forming method comprising:
a step of forming a resist film on a surface of a semiconductor substrate using the semiconductor substrate from which a defect on the surface is removed using the defect removal method according to claim 15; and
a step of forming a pattern on the resist film.

26. A method of manufacturing an electronic device, the method comprising:
a step of forming a resist film on a surface of a semiconductor substrate using the semiconductor substrate from which a defect on the surface is removed using the defect removal method according to claim 15; and
a step of forming a pattern of an electronic device on the resist film.
